(19) United States
(12) Patent Application Publication
(10) Pub. No.: US 2026/0226617 A1
(43) Pub. Date: Aug. 6, 2026

(54) FORMING HALOGEN-DOPED DIELECTRIC FILMS

(71) Applicant: Lam Research Corporation, Fremont, CA (US)

(72) Inventors: Mary Waddington GRUMBLES, Portland, OR (US); Douglas Walter AGNEW, Portland, OR (US); Daniel Christopher MESSINA, Beaverton, OR (US); Jennifer Leigh PETRAGLIA, Portland, OR (US); Ravi KUMAR, Beaverton, OR (US); Konner Eric Kurt HOLDEN, Woodburn, OR (US); Tao ZHANG, Tigard, OR (US); Pulkit AGARWAL, Beaverton, OR (US)

(21) Appl. No.: 19/134,704

(22) PCT Filed: Dec. 15, 2023
(86) PCT No.: PCT/US2023/084335

§ 371 Date: May 30, 2025

Related U.S. Application Data
(60) Provisional application No. 63/476,244, filed on Dec. 20, 2022.

(51) Int. Cl. C23C 16/455; C23C 16/40; C23C 16/52

(52) U.S. Cl. CPC C23C 16/45536; C23C 16/401; C23C 16/45553; C23C 16/52

(57) ABSTRACT

One example provides a method of forming a halogen-doped dielectric film. The method comprises forming a dielectric film comprising a plurality of dielectric film layers. The method further comprises performing a plasma doping process after forming the dielectric film. The plasma doping process comprises introducing a halogen-containing precursor into a plasma, and exposing the dielectric film to reactive halogen-containing species generated in the plasma from the halogen-containing precursor, thereby forming the halogen-doped dielectric film.

### BACKGROUND

Semiconductor device fabrication processes involves many steps of material deposition, patterning and removal to form integrated circuits on substrates. Various methods can be used to deposit films of materials onto a substrate. As an example, atomic layer deposition (ALD) forms a film layer-by-layer using multiple deposition cycles (ALD cycles). In an ALD cycle, a film precursor is adsorbed onto a surface of a substrate in a process chamber. Excess film precursor is purged from the chamber. The adsorbed film precursor then is chemically converted into a film on the substrate, for example, by oxidation.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

One example provides a method of forming a halogen-doped dielectric film. The method comprises forming a dielectric film comprising a plurality of dielectric film layers. The method further comprises performing a plasma doping process after forming the dielectric film. The plasma doping process comprises introducing a halogen-containing precursor into a plasma, and exposing the dielectric film to reactive halogen-containing species generated in the plasma from the halogen-containing precursor, thereby forming the halogen-doped dielectric film.

In some such examples, the halogen-containing precursor alternatively or additionally comprises one or more of fluorine, hydrogen fluoride, nitrogen trifluoride, sulfur tetrafluoride, sulfur hexafluoride, chlorine trifluoride, chlorine pentafluoride, boron trifluoride, phosphorus trifluoride, a fluorocarbon, a chlorofluorocarbon, a chalcogen, a hydrofluorocarbon, or an interhalogen.

In some such examples, the halogen-containing precursor alternatively or additionally comprises anhydrous HF.

In some such examples, the halogen-containing precursor alternatively or additionally comprises one or more of a chlorine-containing (Cl-containing) species, a bromine-containing (Br-containing) species, or an iodine-containing (I-containing) species.

In some such examples, the dielectric film alternatively or additionally comprises silicon oxide (SiO₂).

In some such examples, a dielectric constant of the halogen-doped dielectric film alternatively or additionally is lower than a lower dielectric constant of the dielectric film.

In some such examples, forming the halogen-doped dielectric alternatively or additionally comprises forming a halogen-doped dielectric film in which the halogen extends through a thickness of the halogen-doped dielectric film as measured by secondary ion mass spectroscopy (SIMS) imaging.

In some such examples, the method alternatively or additionally further comprises heating the substrate to a temperature in the range of 23-1200° C. while performing the plasma doping process.

Another example provides a method of forming a halogen-doped dielectric film. The method comprises performing a plurality of atomic layer deposition (ALD) cycles. Each ALD cycle comprises exposing a substrate in a processing chamber to a dielectric film precursor to adsorb the dielectric film precursor to the substrate. Each ALD cycle further comprises forming a gas mixture in the processing chamber, the gas mixture comprising a halogen-containing precursor, an oxidant, and an inert gas. Each ALD cycle further comprises forming a plasma comprising the gas mixture to form reactive halogen-containing species and reactive oxidant species, and reacting the dielectric film precursor adsorbed to the substrate with the reactive halogen-containing species and the reactive oxidant species to form the halogen-doped dielectric film.

In some such examples, the gas mixture alternatively or additionally further comprises hydrogen.

In some such examples, the dielectric film precursor alternatively or additionally comprises a silicon-containing precursor.

In some such examples, the silicon-containing precursor alternatively or additionally comprises an aminosilane.

In some such examples, the halogen-containing precursor alternatively or additionally comprises a fluorine containing precursor.

In some such examples, the halogen-containing precursor alternatively or additionally comprises one or more of fluorine, hydrogen fluoride, nitrogen trifluoride, sulfur tetrafluoride, sulfur hexafluoride, chlorine trifluoride, chlorine pentafluoride, boron trifluoride, phosphorus trifluoride, a fluorocarbon, a chlorofluorocarbon, a chalcogen, a hydrofluorocarbon, or an interhalogen.

In some such examples, the halogen-containing precursor alternatively or additionally comprises anhydrous HF.

In some such examples, the halogen-containing precursor alternatively or additionally comprises one or more of a chlorine-containing species, a bromine-containing species, or an iodine-containing species.

Yet another example provides a processing tool. The processing tool comprises a processing chamber, a plasma generator, and one or more gas inlets into the processing chamber. The processing tool further comprises flow control hardware fluidly connecting one or more gas sources to the one or more gas inlets. The processing tool further comprises a controller. The controller is configured to perform an atomic layer deposition (ALD) process comprising a plurality of ALD cycles to form a dielectric film on a substrate in the processing chamber. The controller is further configured to control the plasma generator to form a plasma after performing the ALD process comprising the plurality of ALD cycles. The controller is further configured to control the flow control hardware to introduce a halogen-containing precursor into the plasma to generate reactive halogen-containing species to dope the dielectric film with a halogen.

In some such examples, the processing tool alternatively or additionally comprises a substrate heater, and wherein the controller is configured to control the substrate heater to heat the substrate to a temperature in a range of 23-1200° C. while exposing the dielectric film to the reactive halogen-containing species.

In some such examples, the processing tool alternatively or additionally comprises a halogen-containing precursor supply.

In some such examples, the halogen-containing precursor supply alternatively or additionally comprises one or more of fluorine, hydrogen fluoride, nitrogen trifluoride, sulfur tetrafluoride, sulfur hexafluoride, chlorine trifluoride, chlorine pentafluoride, boron trifluoride, phosphorus trifluoride, a fluorocarbon, a chlorofluorocarbon, a chalcogen, a hydrofluorocarbon, or an interhalogen.

### BRIEF DESCRIPTION OF THE DRAWINGS

FIG. 1 shows a block diagram of an example processing tool.

FIG. 2 shows a flow diagram illustrating an example process for forming a halogen-doped dielectric film.

FIGS. 3A-3D schematically show example substrate structures formed in an example implementation of the process of FIG. 2.

FIG. 4 shows a flow diagram illustrating another example process for forming a halogen-doped dielectric film.

FIG. 5 schematically illustrates reaction zones in a spatial atomic layer deposition (ALD) process.

FIG. 6 schematically shows an overhead view of a substrate support that can rotate a substrate through different reaction zones to perform a spatial ALD process.

FIG. 7 schematically shows an example processing chamber configured for spatial ALD.

FIG. 8 shows a block diagram of an example computing device.

### DETAILED DESCRIPTION

The term “aspect ratio” generally represents a ratio between a depth of a feature of a substrate and an average width of the feature. The term “high aspect ratio (HAR)” generally represents features with depth: width ratios of higher than 1:1.

The term “atomic layer deposition” (ALD) generally represents a process in which a film is formed on a substrate in one or more individual layers by sequentially adsorbing a precursor to a substrate and then chemically transforming the adsorbed precursor to form a film layer. Examples of ALD processes comprise plasma-enhanced ALD (PEALD) and thermal ALD (TALD). PEALD and TALD respectively utilize a plasma of a reactive gas and heat to facilitate a chemical conversion of a precursor adsorbed to a substrate to a film on the substrate. The terms “growth”, “deposition”, and variants thereof also can be used to refer to film formation. The term “temporal ALD” generally represents ALD processes that form film layers by controlling the timing and duration of sequential reaction steps while a substrate remains stationary. The term “spatial ALD” generally represents ALD processes in which a substrate is sequentially moved between different reaction zones, each configured for a specific process step.

The terms “atomic layer deposition cycle” and “ALD cycle” generally represent a single cycle of adsorbing a chemical precursor on a substrate surface and then chemically transforming the adsorbed chemical precursor to form a film layer on the substrate.

The term “carbon-containing precursor” generally represents a carbon-containing compound that can be introduced into a processing chamber in gas phase to form a dielectric film comprising carbon. Example carbon-containing dielectric films include silicon carbide and silicon oxycarbide. Example carbon-containing can comprise alkanes having a general formula CₙH₂ₙ₊₂ where n is an integer in a range of 1 to 10 (such as, methane, ethane, etc.), alkenes having a general formula CₙH₂ₙ where n=2 to 10 (such as, ethylene, propylene, etc.), and alkynes having a general formula CₙH₂ₙ₋₂ where n=2 to 10 (such as, acetylene, propyne, etc.), that are gas-phase under processing conditions. Other examples of carbon-containing precursors can comprise cyclic hydrocarbons including aromatics, nitrogen-containing compounds including alkyl amines, and oxygen-containing compounds including alcohols, ketones, esters, aldehydes, and ethers that are gas-phase under processing conditions.

The term “dielectric film” generally represents a layer of an insulating material that can be polarized by an applied electric field. Example dielectric films comprise silicon oxide (SiO₂), silicon nitride (Si₃N₄), silicon oxynitride (Si₃N₄₍₁₋ₓ₎O₆ₓ), silicon carbide (SiC), silicon oxycarbide (SiO₂₍₁₋ₓ₎Cₓ), aluminum nitride (AlN), aluminum oxide (Al₂O₃), tin oxides (e.g. SnO, SnO₂), gallium nitride (GaN), boron nitride (BN) and gallium arsenide (GaAs) films.

The term “doping” and variants thereof generally represent the introduction of an impurity into a material for the purpose of modifying one or more physical properties of the material. The term “dopant” generally represents a chemical species introduced into another material as an impurity in a doping process.

The term “flow control hardware” generally represents components configured to place one or more chemical sources in fluid connection with a processing chamber. Flow control hardware can comprise one or more mass flow controllers and/or valves, for example. Example chemical sources include dielectric film precursor sources, halogen-containing precursor sources, reactant gas sources, and inert gas sources.

The term “forming a gas mixture” generally represents either of or both of mixing a plurality of gases before introducing the plurality of gases into the processing chamber, or mixing a plurality of gases in the processing chamber.

The term “halogen doping” and variants thereof generally represents a process of doping a dielectric film with a halogen species. The halogen can comprise fluorine, chlorine, bromine or iodine. Halogen doping can be used, for example, to lower a dielectric constant of a dielectric film such as a silicon oxide film.

The term “halogen-containing precursor” generally represents a chemical entity comprising a halogen that can be used to dope a dielectric film with the halogen. Examples of fluorine-containing precursors include fluorine (F₂), boron trifluoride (BF₃), phosphorus trifluoride (PF₃), nitrogen trifluoride (NF₃), sulfur tetrafluoride (SF₄), sulfur hexafluoride (SF₆), hydrogen fluoride (HF), chlorine trifluoride (ClF₃), chlorine pentafluoride (ClF₅), as well as fluorocarbons, hydrofluorocarbons, chlorofluorocarbon, chalcogens and interhalogens that are gas phase under processing conditions. term “fluorocarbon” generally represents a molecule comprising one or more carbon atoms and one or more fluorine atoms. The term “hydrofluorocarbon” generally represents a molecule comprising one or more carbon atoms, one or more hydrogen atoms, and one or more fluorine atoms. The term “chlorofluorocarbon” generally represents a molecule comprising one or more carbon atoms, one or more chlorine atoms, and one or more fluorine atoms. The term “interhalogen” generally represents a molecule comprising two or more different halogen atoms. The term “chalcogen” generally represents a molecule comprising oxygen, sulfur, selenium and/or tellurium atoms. Other example halogen-containing precursors comprise Cl-containing species, Br-containing species, and I-containing species. Hydrogen chloride (HCl), hydrogen bromide (HBr), and hydrogen iodide (HI) are more specific examples of other halogen-containing precursors.

The term “inert gas” generally represents a gas phase material that does not react with other chemicals in a processing chamber during substrate processing. Example inert gases include helium (He), neon (Ne), argon (Ar), krypton (Kr), and xenon (Xe), as well as nitrogen (N₂) in some processes.

The term “plasma” generally represents a gas comprising cations and free electrons. The term “in-situ plasma” generally represents a plasma formed at a processing station in a processing chamber. The term “remote plasma” generally represents a plasma formed at a location away from a processing station in a processing chamber.

The term “plasma generator” generally represents a combination of components that can be used to form a plasma. Example components include a radiofrequency power source, an impedance matching network, and one or more electrodes.

The term “precursor” generally represents a chemical species that adsorbs to a substrate surface in an ALD process. The precursor is reacted with a reactant to convert the adsorbed precursor to a film layer.

The term “processing chamber” generally represents an enclosure in which chemical and/or physical processes are performed on substrates. The pressure, substrate temperature and atmospheric composition within a processing chamber can be controllable to perform the chemical and/or physical processes.

The term “processing tool” may generally represent a machine comprising a processing chamber and other hardware configured to enable processing to be carried out in the processing chamber.

The term “processing station” generally represents a location in a processing chamber at which a substrate is positioned during processing.

The term “reactant” generally represents a chemical species that reacts with a precursor adsorbed to a substrate surface to form a film layer in an ALD process. A reaction between a reactant and a precursor can be facilitated by thermal energy and/or a plasma in various processes.

The term “silicon-containing precursor” generally represents a chemical species that contains one or more silicon atoms and that can adsorb to a substrate surface in an ALD process to be converted into a silicon-containing dielectric film. Example silicon-containing precursors can include materials having the general structure:

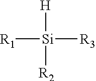

where R₁, R₂ and R₃ can be the same or different substituents, and can include silanes, siloxy groups, amines, halides, hydrogen, or organic groups, such as alkylamines, alkoxy, alkyl, alkenyl, alkynyl and aromatic groups. More specific example silicon-containing precursors include polysilanes (H₃Si—(SiH₂)ₙ—SiH₃), where n≥1, such as silane, disilane, trisilane, tetrasilane, and trisilylamine. In some examples, the silicon-containing precursor is an alkoxysilane. Alkoxysilanes that can be used include the following: Hₓ—Si—(OR)_{y}, where x=1-3, x+y=4 and each R is a substituted or unsubstituted alkyl, alkenyl, alkynyl or aromatic group; and Hₓ(RO)_{y}, —Si—Si—(OR)_{y}Hₓ, is a substituted or unsubstituted alkyl, alkenyl, alkynyl or aromatic group. Further examples of silicon-containing precursors include tetraethyl orthosilicate (TEOS), tetramethoxysilane (TMOS), methylsilane, trimethylsilane (3 MS), ethylsilane, butasilanes, pentasilanes, octasilanes, heptasilane, hexasilane, cyclobutasilane, cycloheptasilane, cyclohexasilane, cyclooctasilane, cyclopentasilane, 1,4-dioxa-2,3,5,6-tetrasilacyclohexane, diethoxymethylsilane (DEMS), diethoxysilane (DES), dimethoxymethylsilane, dimethoxysilane (DMOS), methyl-diethoxysilane (MDES), methyl-dimethoxysilane (MDMS), t-butoxydisilane, triethoxysilane (TES), and trimethoxysilane (TMS or TriMOS). In some examples, the silicon-containing precursor can comprise a siloxane. Example siloxanes include octamethylcyclotetrasiloxane (OMCTS), octamethoxydodecasiloxane (OMODDS), tetramethylcyclotetrasiloxane (TMCTS), triethoxysiloxane (TRIES), and tetraoxymethylcyclotetrasiloxane (TOMCTS). Further, in some examples, the silicon-containing precursor can be an aminosilane, such as bisdiethylaminosilane, diisopropylaminosilane, bis(t-butylamino) silane (BTBAS), di-sec-butylaminosilane, or tris(dimethylamino) silane (3DMAS). Aminosilane precursors include the following: Hₓ—Si—(NR)_{y}, where x=1-3, x+y=4, and R is a substituted or unsubstituted alkyl, alkenyl, alkynyl or aromatic group or hydride group. In some examples, a halogen-containing silane can be used such that the silane includes at least one hydrogen atom. Such a silane can have a chemical formula of SiXₐH_{y} where y≥1. Dichlorosilane (H₂SiCl₂) can be used in some examples.

The term “through-substrate via” generally represents an electrically conductive pathway in an integrated circuit that extends through a semiconductor substrate.

As mentioned above, atomic layer deposition (ALD) can be used to deposit dielectric films. ALD is particularly well-suited for forming conformal films in high aspect ratio (HAR) features due to the layer-by-layer nature of ALD film growth. As one example of a HAR feature, a through-substrate via (TSV) can be lined with a dielectric layer using ALD.

However, as feature sizes continue to decrease in integrated circuits, crosstalk and charge buildup pose concerns. The use of dielectric materials with lower dielectric constants can help mitigate issues with crosstalk and charge buildup. One approach to lower the dielectric constant of a silicon oxide dielectric film is to dope the silicon oxide dielectric film with fluorine. However, traditional methods of forming halogen-doped dielectric films, such as fluorine-doped silicon oxide films, employ temperatures that can be unsuitably high for some semiconductor fabrication processes, such as damascene processes. Further, such methods can lack the capacity to form halogen-doped silicon oxide as a conformal film in HAR features.

A more recent method for forming a conformal dielectric film doped with a halogen is to use an ALD process in which ALD cycles and halogen doping steps are performed in an alternating matter. First, an ALD cycle is performed to deposit a layer of a dielectric film. Then, a halogen doping step is performed by exposing the layer of the dielectric film to a halogen-containing precursor in the presence of a plasma. Such a process can be used to form a conformal halogen-doped dielectric film in HAR features at temperatures suitably low for damascene processes. However, performing a plasma doping step after each ALD cycle increases the process time for forming the halogen-doped dielectric film compared to forming an undoped dielectric film. As such, the halogen doping steps can reduce throughput compared to the deposition of a dielectric film without halogen doping.

Accordingly, examples are disclosed that relate to efficiently forming halogen-doped dielectric films. The disclosed examples can utilize temperatures suitably low for damascene processes. Further, the disclosed examples can be used to form halogen-doped conformal dielectric films in HAR features.

One disclosed example provides a method of forming a halogen-doped dielectric film. The method comprises forming a dielectric film comprising a plurality of dielectric film layers using a plurality of ALD cycles. The method further comprises performing a plasma doping process after forming the dielectric film. The plasma doping process comprises introducing a halogen-containing precursor into a plasma. The plasma doping process further comprises exposing the dielectric film to reactive halogen-containing species generated in the plasma from the halogen-containing precursor, thereby forming the halogen-doped dielectric film. In some such examples, the plasma doping process can be performed after fully forming the dielectric film. Performing the plasma doping process after fully forming the dielectric film can reduce process time and increases throughput compared to performing halogen doping steps between individual ALD cycles.

Another example provides a method of forming a halogen-doped dielectric film. The method comprises performing a plurality of an ALD cycles. Each ALD cycle comprises exposing a substrate in a processing chamber to a dielectric film precursor to adsorb the dielectric film precursor to the substrate. Each ALD cycle further comprises forming a gas mixture in the processing chamber, the gas mixture comprising a halogen-containing precursor, an oxidant, and an inert gas. In some examples, the gas mixture also can include hydrogen. Each ALD cycle further comprises forming a plasma comprising the gas mixture to form reactive halogen-containing species and reactive oxidant species and reacting the dielectric film precursor adsorbed to the substrate with the reactive species to form the halogen-doped dielectric film. In such examples, the halogen doping is performed during the ALD cycles used to deposit individual layers of the dielectric film. This likewise can reduce process time and increase throughput compared to performing halogen doping between individual ALD cycles.

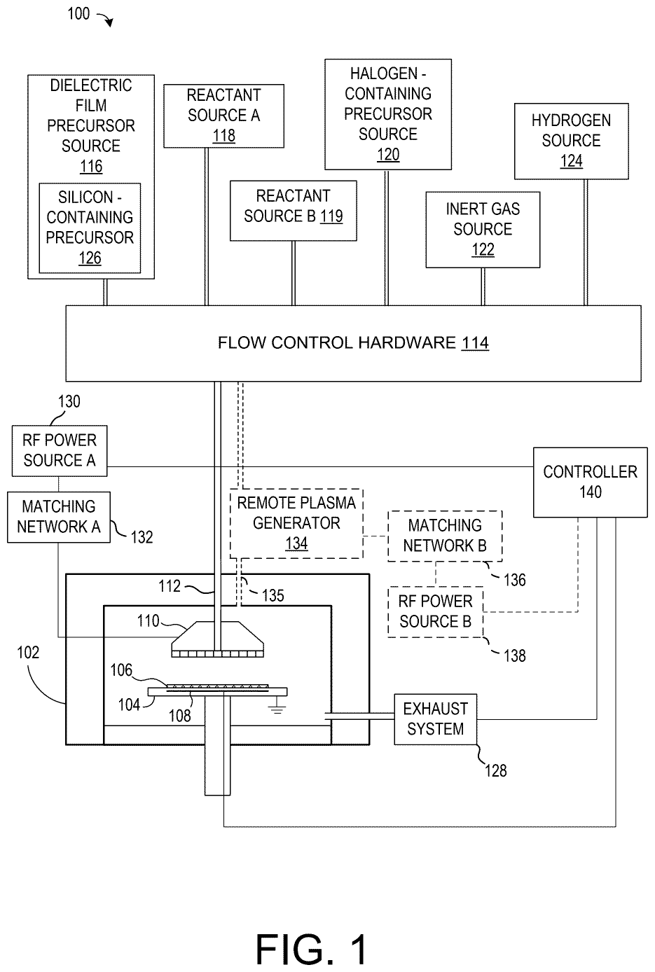

FIG. 1 shows a schematic view of an example processing tool 100 for performing a deposition process. Processing tool 100 comprises an ALD tool. Processing tool 100 can be used form a halogen-doped conformal dielectric film. Processing tool 100 comprises a processing chamber 102. Processing tool 100 further comprises a substrate support 104 within the processing chamber 102 for supporting a substrate 106. Substrate support 104 can comprise a pedestal, a chuck, and/or any other suitable structure. Substrate support 104 further includes a substrate heater 108. Processing tool 100 further comprises a showerhead 110 within processing chamber 102. In other examples, a nozzle and/or other suitable inlet hardware can be used.

Processing tool 100 further comprises one or more processing gas inlets for introducing processing gases into processing chamber 102. One example processing gas inlet is shown as processing gas inlet 112. Processing gas inlet 112 is configured to admit a flow of one or more processing gases to showerhead 110 for distribution. Processing tool 100 further comprises flow control hardware 114 that fluidly connects processing gas sources and processing chamber 102. The processing gas sources include a dielectric film precursor source 116, a reactant source A 118, an optional reactant source B 119, a halogen-containing precursor source 120, an inert gas source 122 and an optional hydrogen source 124.

In some examples, dielectric film precursor source 116 comprises a silicon-containing precursor source 126 to form silicon-based dielectric films having silicon. Example silicon-based dielectric films include silicon oxide, silicon nitride, silicon oxynitride, silicon carbide and silicon oxycarbide. In other examples, dielectric film precursor source 116 can comprise precursors to form aluminum nitride, aluminum oxide, tin oxide, gallium nitride, boron nitride or gallium arsenide films.

Silicon-containing precursor source 126 comprises any suitable silicon-containing precursor. Example silicon-containing precursors can include materials having the general structure:

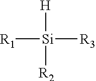

where R₁, R₂ and R₃ can be the same or different substituents, and can include silanes, siloxy groups, amines, halides, hydrogen, or organic groups, such as alkylamines, alkoxy, alkyl, alkenyl, alkynyl and aromatic groups. More specific example silicon-containing precursors include polysilanes (H₃Si—(SiH₂)ₙ—SiH₃), where n≥1, such as silane, disilane, trisilane, tetrasilane, and trisilylamine. In some examples, the silicon-containing precursor is an alkoxysilane. Alkoxysilanes that can be used include the following: Hₓ—Si—(OR)_{y}, where x=1-3, x+y=4 and each R is a substituted or unsubstituted alkyl, alkenyl, alkynyl or aromatic group; and Hₓ(RO)_{y}, —Si—Si—(OR)_{y}Hₓ, is a substituted or unsubstituted alkyl, alkenyl, alkynyl or aromatic group. Further examples of silicon-containing precursors include tetraethyl orthosilicate (TEOS), tetramethoxysilane (TMOS), methylsilane, trimethylsilane (3MS), ethylsilane, butasilanes, pentasilanes, octasilanes, heptasilane, hexasilane, cyclobutasilane, cycloheptasilane, cyclohexasilane, cyclooctasilane, cyclopentasilane, 1,4-dioxa-2,3,5,6-tetrasilacyclohexane, diethoxymethylsilane (DEMS), diethoxysilane (DES), dimethoxymethylsilane, dimethoxysilane (DMOS), methyl-diethoxysilane (MDES), methyl-dimethoxysilane (MDMS), t-butoxydisilane, triethoxysilane (TES), and trimethoxysilane (TMS or TriMOS). In some examples, the silicon-containing precursor can comprise a siloxane. Example siloxanes include octamethylcyclotetrasiloxane (OMCTS), octamethoxydodecasiloxane (OMODDS), tetramethylcyclotetrasiloxane (TMCTS), triethoxysiloxane (TRIES), and tetraoxymethylcyclotetrasiloxane (TOMCTS). Further, in some examples, the silicon-containing precursor can be an aminosilane, such as bisdiethylaminosilane, diisopropylaminosilane, bis(t-butylamino) silane (BTBAS), di-sec-butylaminosilane, or tris(dimethylamino) silane (3DMAS). Aminosilane precursors include the following: Hₓ—Si—(NR)_{y}, where x=1-3, x+y=4, and R is a substituted or unsubstituted alkyl, alkenyl, alkynyl or aromatic group or hydride group. In some examples, a halogen-containing silane can be used such that the silane includes at least one hydrogen atom. Such a silane can have a chemical formula of SiXₐH_{y} where y≥1. Dichlorosilane (H₂SiCl₂) can be used in some examples.

In some examples, reactant source A 118 comprises an oxidant to oxidize the silicon-containing precursor or other dielectric film precursor. Example oxidants include oxygen (O₂), ozone (O₃), one or more oxides of nitrogen (e.g. nitrous oxide (N₂O)), water vapor (H₂O), and hydrogen peroxide (H₂O₂). In some examples, a mixture of two or more different oxidants can be used.

In other examples, reactant source A 118 can comprise nitrogen (N₂), ammonia (NH₃), or other nitrogen-containing reactant to form a silicon nitride film. In further examples, reactant source A 118 can comprise a reactant that can be used to form silicon carbide from a silicon-containing precursor. Examples include carbon-containing molecules that are gas phase under processing conditions. More specific examples can include the carbon-containing precursors listed above.

Optional reactant source B 119 can comprise a reactant for forming a ternary dielectric film in combination with the dielectric precursor and the reactant of reactant source A. For example, where the dielectric film is a silicon oxycarbide film, reactant source A can comprise an oxygen-containing reactant, and optional reactant source B can comprise a carbon-containing reactant. Examples of oxygen-containing reactants and carbon-containing reactants include those listed above. Likewise, where the dielectric film is a silicon oxynitride film, reactant source A can comprise an oxygen-containing reactant, and optional reactant source B can comprise a nitrogen-containing reactant.

Halogen-containing precursor source 120 (also referred to herein as a halogen-containing precursor supply) comprises a halogen-containing chemical species that can be introduced into processing chamber 102 in a gas phase. Halogen-containing precursor source 120 can comprise one or more of a F-containing species, a Cl-containing species, a Br-containing species, or an I-containing species. In more specific examples, halogen-containing precursor source 120 can comprise one or more of HF, BF₃, PF₃, F₂, NF₃, SF₄, SF₆, ClF₃, ClF₅, a fluorocarbon, a hydrofluorocarbon, or an interhalogen that is gas phase under processing conditions. In further examples, halogen-containing precursor source 120 can comprise hydrogen chloride (HCl), hydrogen bromide (HBr), or hydrogen iodide (HI). The halogen-containing precursor source 120 can comprise a flow-over-vapor delivery system where the halogen-containing precursor is HBr or HI

Inert gas source 122 can comprise any suitable gas. Examples include one or more of nitrogen (N₂), helium (He), neon (Ne), argon (Ar), krypton (Kr) or xenon (Xe). In some examples, one or more additional inert gas sources can be included, each providing a different inert gas. Inert gas source 122 can be used as a diluent during a deposition process, as a gas for forming a plasma, and/or for purging.

In some examples, hydrogen can be used as an additional gas in a dielectric film deposition process and/or a halogen doping process. As such, flow control hardware 114 can be fluidly connected to optional hydrogen source 124.

Processing tool 100 further comprises an exhaust system 128. Exhaust system 128 is configured to remove gases from processing chamber 102. Exhaust system 128 can comprise any suitable hardware. Example hardware includes one or low vacuum pumps and/or one or more high vacuum pumps.

In some examples, substrate heater 108 is used to provide thermal energy to facilitate a dielectric film deposition process. Substrate heater 108 further can be used to provide thermal energy for a plasma doping process. In such examples, the substrate heater 108 can be used to heat the substrate to a temperature in the range of 23-1200° C.

In some examples, an in-situ plasma can be used to facilitate a dielectric film deposition process and/or a halogen doping process. An in-situ plasma can be generated using a radiofrequency power source A 130 and a matching network A 132. Radiofrequency power can be applied to showerhead 110, as depicted. Further, substrate support 104 can be connected to electrical ground. In other examples, radiofrequency power can be applied to substrate support 104, and showerhead 110 can be grounded. The in-situ plasma can be used to provide the energy to generate chemically active species in the gas phase. In yet other examples, radiofrequency power of a first frequency and radiofrequency power of a second frequency may be applied to the showerhead, where the second frequency is lower than the first frequency.

In other examples, a remote plasma generator 134 can be used to generate a remote plasma provide reactive species for the deposition process. The term “remote plasma” refers generally to a plasma to which a substrate is not directly exposed during a deposition process. Instead, reactive species from a remote plasma diffuse to substrate 106. In the depicted example, remote plasma generator 134 is shown as being fluidly coupled with processing chamber 102 by an inlet 135. In other examples, a remote plasma generator can be contiguous with a processing chamber but located away from processing stations. Where remote plasma generator 134 is used, processing tool 100 can comprise a radiofrequency power source B 136 electrically connected to remote plasma generator 134. Likewise, processing tool 100 further can comprise a matching network B 138 for impedance matching of the radiofrequency power source B 136.

Radiofrequency power source A 130 and radiofrequency power source B 138 each can be configured for any suitable frequency and power. Examples of suitable frequencies include 400 kHz, 13.56 MHz, 27 MHz, 60 Mz, and 90 MHz. Examples of suitable powers include powers between 50 W (watts) and 6500 W. In some examples, radiofrequency power source A 130 and/or radiofrequency power source B 138 can be configured to operate at a plurality of different frequencies and/or powers. In some examples, two or more different frequencies of radiofrequency power can be used together. While processing tool 100 is illustrated as being configured to generate both a remote plasma and an in-situ plasma, in some examples, a processing tool can be configured to generate one of a remote plasma or an in-situ plasma.

Flow control hardware 114 can be controlled to flow processing chemicals from sources 116, 118, 119, 120, 122, 124 or 126 into processing chamber 102 through gas inlet 112. In some examples, flow control hardware 114 can also be configured to control the flow of one or more chemicals into remote plasma generator 134. Flow control hardware 114 schematically represents any suitable components related to flowing gas into processing chamber 102 (and remote plasma generator 134 in some examples). For example, flow control hardware 114 can comprise one or more mass flow controllers and/or valves controllable to place a selected chemical source in fluid connection with processing chamber 102.

Controller 140 is operatively coupled to controllable components of processing tool 100. For example, controller 140 is operatively coupled to substrate heater 108, flow control hardware 114, exhaust system 128, radiofrequency power source A 130, and radiofrequency power source B 136. Controller 140 further can be operatively coupled to any other suitable component of processing tool 100. Controller 140 is configured to control various functions of processing tool 100 to perform a doped dielectric film deposition process. Example processes are described below.

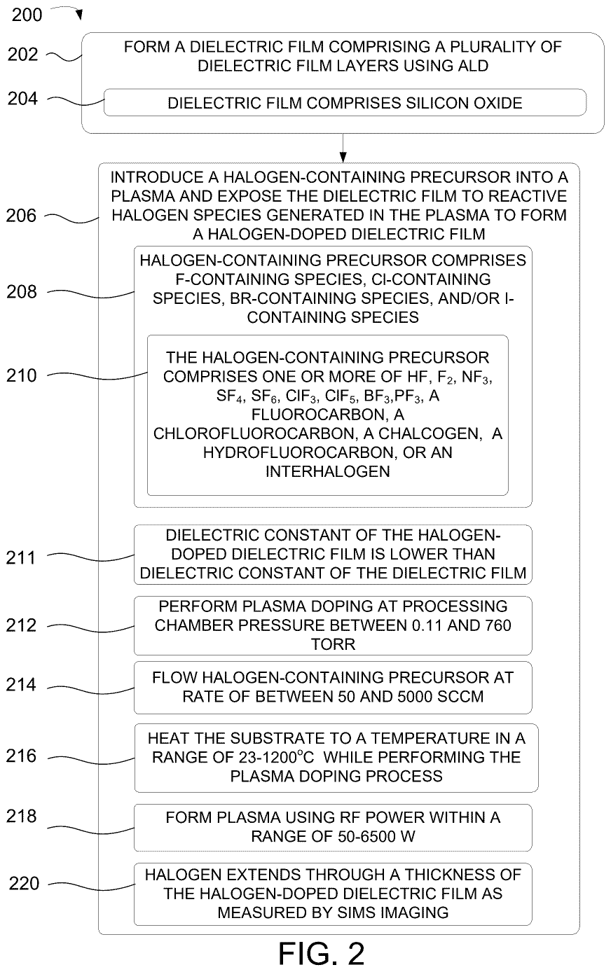

FIG. 2 shows a flow diagram depicting an example method 200 of forming a halogen-doped dielectric film. Method 200 can be implemented on a processing tool at least in part by computer-readable instructions executed by a controller of a processing tool. Processing tool 100 is an example of a processing tool on which method 200 can be performed.

At step 202, method 200 comprises forming, on a substrate in a processing chamber, a dielectric film comprising a plurality of dielectric film layers using ALD. In some examples, the dielectric film can comprise a silicon oxide film 204. In other examples, the dielectric film can comprise another dielectric material. Examples include silicon nitride, silicon oxynitride, silicon carbide, silicon oxycarbide, aluminum nitride, aluminum oxide, tin oxides, gallium nitride, boron nitride and gallium arsenide. The dielectric film comprises a plurality of dielectric film layers. Each dielectric film layer is deposited by an ALD cycle. In some examples the dielectric film can be deposited in a HAR feature. As an example, the dielectric film can be deposited in a through-substrate via. Each ALD cycle comprises exposing the substrate to a dielectric film precursor, purging the deposition chamber, exposing the substrate to a reactant, and again purging the deposition chamber. A plasma can be used to generate reactive species from the reactant. As an example, a silicon oxide film can be formed by exposing the substrate to a silicon-containing precursor, and then oxidizing adsorbed silicon-containing precursor on the substrate to form silicon oxide.

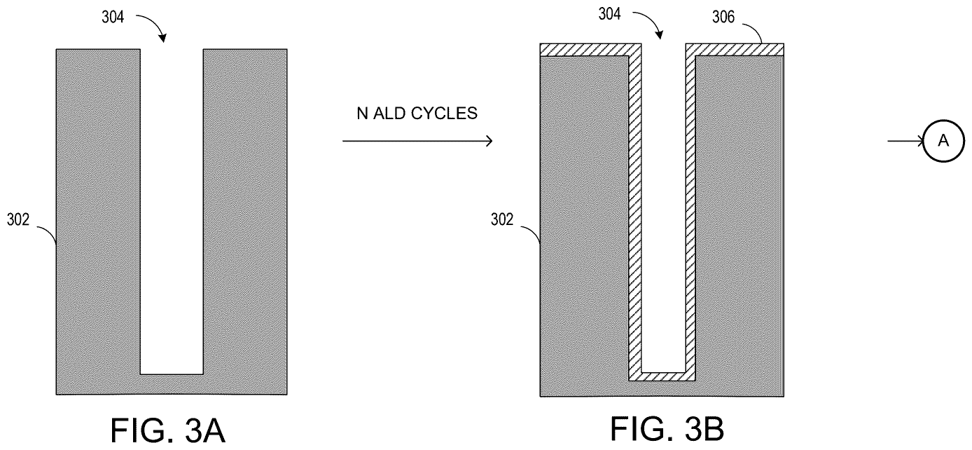

FIGS. 3A-3D schematically illustrate structures formed in an example implementation of method 200. First, FIG. 3A schematically illustrates a substrate 302 comprising an etched feature 304. Etched feature 304 can represent a HAR feature formed in a through-substrate via fabrication process. Dimensions of substrate 302 and etched feature 304 are exaggerated and not to scale.

In a through-substrate via process, etched feature 304 is eventually filled with a conducting material to form an electrically conductive path that extends through the substrate 302. However, a dielectric film is first deposited in etched feature 304 to insulate the substrate 302. In FIGS. 3A-3D, the depicted dimensions of the substrate 302 and the etched feature 304 are exaggerated for the purpose of illustration. In some examples, a through-substrate via can have an aspect ratio within a range of 1:1 to 300:1. Further, in other examples, FIGS. 3A-3D can generally represent other HAR features than an etched feature formed in a through-substrate via fabrication process.

FIG. 3B illustrates a dielectric film 306 that has been deposited within the etched feature 304 of substrate 302 using an ALD process. Dielectric film 306 is an example of a dielectric film formed at step 202 in FIG. 2. Dielectric film 306 is formed by performing plurality of ALD cycles on substrate 302 in a processing chamber. As described above, each ALD cycle can comprise adsorbing a dielectric film precursor on the surface of the substrate 302. In some examples, the dielectric film precursor can comprise a silicon-containing precursor. Example silicon-containing precursors include those listed above. After adsorbing the dielectric film precursor to the surface of the substrate 302, the processing chamber is purged of excess dielectric film precursor. Then, a plasma is formed. Next, a reactant is introduced to the plasma. The plasma creates reactive species from the reactant. The reactive species convert the dielectric film precursor adsorbed to the substrate to a layer of the dielectric film. After forming the layer of the dielectric film, the chamber is again purged to complete the ALD cycle. A plurality of ALD cycles can be used to deposit the dielectric film 306 in a layer by layer manner. A thickness of dielectric film 306 can be controlled by controlling a number of ALD cycles used to form dielectric film 306.

After forming dielectric film 306, a plasma doping process is performed. Returning to FIG. 2, method 200 comprises, at step 206, introducing a halogen-containing precursor into a plasma and exposing the dielectric film to reactive halogen-containing species generated in the plasma to form a halogen-doped dielectric film. In some examples, the processing chamber is purged prior to performing the plasma doping process. In other examples, purging prior to the halogen doping process can be omitted.

FIG. 3C schematically depicts an example plasma doping process. As illustrated, substrate 302 comprising dielectric film 306 is exposed to a plasma 308 comprising a halogen-containing precursor 310 and optionally an inert gas 312. Reactive halogen-containing species are formed in the plasma 308. The reactive halogen-containing species can then react with the dielectric film 306 to form a doped dielectric film. FIG. 3D illustrates a doped dielectric film 314 formed by the plasma doping of dielectric film 306 of FIGS. 3B-3C.

In some examples, the plasma doping process is performed after deposition of the dielectric film is complete. Performing the plasma doping process after deposition of the dielectric film is complete can reduce processing times compared to performing a halogen doping process after each ALD cycle. Thus, the disclosed examples can help to increase substrate throughput. A plasma doping process according to the disclosed examples may incorporate a halogen into an entire thickness of a film without performing doping processes between each individual ALD cycle. For example, it has been found that fluorine can be incorporated into a silicon oxide film having a thickness of 100 nanometers by performing a fluorine plasma doping process after completely forming the silicon oxide film. Also, because the halogen doping is performed after the dielectric film has been completely formed, compatibility issues between the dielectric film precursor and the halogen-containing precursor can be avoided. In other examples, the plasma doping process can be performed after a plurality of ALD cycles are used to deposit a portion of a dielectric film. This can still help to increase substrate throughput compared to performing a halogen doping process after each ALD cycle. Also, performing the plasma doping process after a plurality of ALD cycles can utilize the halogen-containing precursor more efficiently than performing a halogen doping step after each ALD cycle.

Any suitable halogen-containing chemical that is gas phase under processing conditions can be used as the halogen-containing precursor. As indicated at 208, the halogen-containing precursor can comprise a fluorine-containing species, a chlorine-containing species, a bromine-containing species, an iodine-containing species, or a combination or a combination of two or more thereof. Example fluorine-containing precursors can include HF, F₂, NF₃, SF₄, SF₆, ClF₃, ClF₅, BF₃, PF₃, as well as fluorocarbons, chlorofluorocarbons, chalcogens, hydrofluorocarbons and interhalogens that are gas-phase under processing conditions, as indicated at 210. Examples of such halogen-containing precursors includes hydrogen chloride, hydrogen bromide, and hydrogen iodide.

As a more specific example, anhydrous hydrogen fluoride can be used as a fluorine-containing precursor to dope a silicon oxide film with fluorine. Hydrogen fluoride can etch SiO₂ in the presence of water. However, it has been found that the use of anhydrous hydrogen fluoride does not lead to etching of a silicon oxide film when used in a plasma doping process as disclosed. Further, anhydrous HF was found to dope full depths of silicon oxide films up to 100 nanometers thick when applied using a plasma as disclosed, as determined from secondary ion mass spectrometry (SIMS).

In examples in which the dielectric film comprises silicon and oxygen (e.g. an SiO₂ film) and the halogen dopant comprises fluorine, the halogen dopant reacts with the film to produce Si—F and Si—OF bonds. This lowers the dielectric constant of the fluorine-doped dielectric film compared to the undoped dielectric film, as indicated in FIG. 2 at 211. For example, the electronegativity of fluorine compared to oxygen decreases a polarizability of a fluorine doped silicon oxide film compared to an undoped silicon oxide film. The extent to which the dielectric constant is reduced by halogen doping depend on the extent of doping and the nature of the halogen. For example, at same dopant concentration, doping with fluorine is likely to result in a lower dielectric constant than doping with chlorine.

A halogen doping process as disclosed can be performed under any suitable processing conditions. In some examples, the halogen doping process is performed at a halogen-containing precursor pressure of between 0.1 and 760 Torr, as indicated at 212. In some examples, this pressure represents a total chamber pressure. In other examples, an inert diluent gas can be used in addition to the halogen-containing precursor. Increasing a partial pressure of the halogen-containing precursor can increase a rate of uptake of the halogen dopant into the dielectric film. This can decrease a time taken to perform the halogen doping. Further, in some examples, the halogen-containing precursor can be added to the processing chamber using a flow rate of between 50 and 5000 sccm (standard cubic centimeters), as indicated at 214. Higher halogen-containing dopant rates also can decrease a time taken to perform the halogen doping.

In some examples, the substrate can be heated to a temperature of between 23 and 1200 degrees Celsius during the plasma doping process, as indicated at 216. In more specific examples, the substrate can be heated to a temperature of between 50 degrees and 600 degrees. Such temperatures may be compatible with damascene processes. Increasing a substrate temperature can enhance the halogen dopant diffusion rate. This can lead to a shorter plasma doping process time and higher throughput. Further, in some examples, a radiofrequency power within a range of 50 W and 6500 W can be used to form an in-situ plasma during the plasma doping process, as indicated at 218. In more specific examples, the radiofrequency power can have a power level of between 1000 and 4500 W. In further examples, the radiofrequency power plasma can have a power level outside of these ranges. Likewise, the radiofrequency power can have any suitable frequency. In some examples, the radiofrequency power has a frequency of 13.56 MHz. Other examples of suitable frequencies include 400 kHz, 27 MHz, 60 Mz, and 90 MHz. In some examples, two or more frequencies of RF power may be used to form an in-situ plasma. In some such examples, RF power of a first frequency can have a power in a range of 50 W to 6500 W, and RF power of a second frequency can have a power in a range of 100 W to 5000 W, where the second frequency is lower than the first frequency. In other examples, one or more processing conditions outside of these ranges can be used.

In some examples, the halogen doping process can be performed using an in-situ plasma. As described above, the in-situ plasma can be a capacitively-coupled plasma or an inductively-coupled plasma in various examples. In some examples, an inert gas also can be used in the plasma. Examples of inert gases that can be used include one or more of helium, neon, argon, krypton, or xenon. In other examples, the halogen doping process can be performed using a remote plasma.

In some examples, deposition and doping can be performed in the same processing tool. Performing the dielectric film deposition and plasma doping process in the same processing tool can reduce the overall cycle time and increase throughput relative to performing these processes in different processing tools. In other examples, plasma doping process can be performed in a processing tool that is different from the processing tool used for depositing the dielectric film.

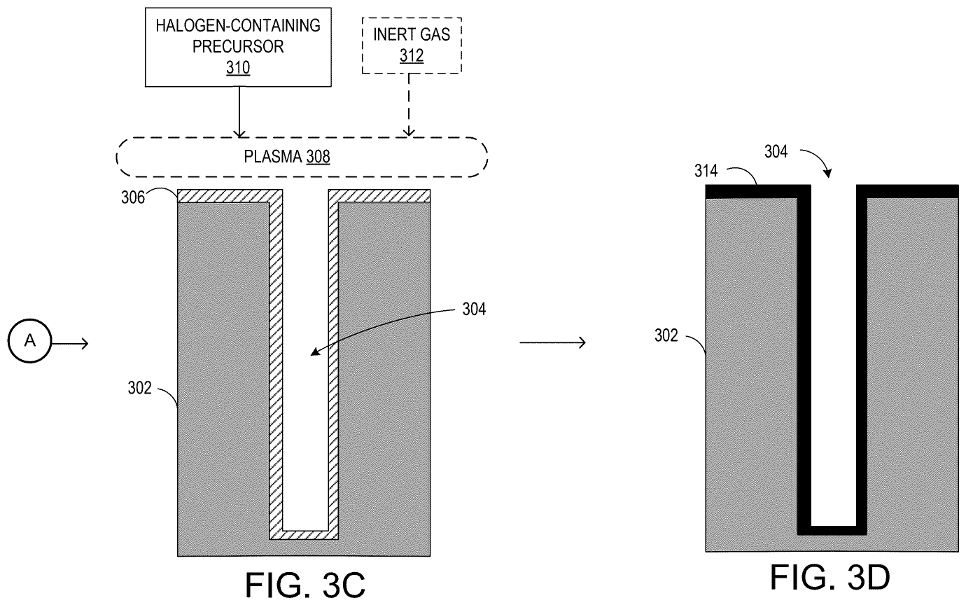

In the examples of FIGS. 2 and 3A-3D, halogen doping is performed after a plurality of ALD cycles are performed to form a dielectric film. FIG. 4 shows a flow diagram of another example method of forming a halogen-doped dielectric film at 400. In method 400, halogen doping is performed during each ALD cycle. This allows a separate doping process after the dielectric film deposition process to be avoided. This likewise allows separate doping steps between ALD cycles to be avoided.

Method 400 comprises, at step 402, exposing a substrate in a processing chamber to a dielectric film precursor to adsorb the dielectric film precursor to the substrate. In some examples, the dielectric film precursor comprises a silicon-containing precursor, as indicated at step 404. In some such examples, the silicon-containing precursor can comprise an aminosilane, as indicated at step 406. In other examples, a silicon-containing precursor can take a form other than an aminosilane. Examples of silicon-containing precursors include those listed above. In yet other examples, a dielectric film precursor other than a silicon-containing precursor can be used. In some examples, the substrate can be exposed to the dielectric film precursor for sufficient time to saturate the substrate surface. This can help to achieve conformal film growth in a HAR feature.

Continuing, method 400 further comprises, at step 408, purging the processing chamber after exposing the substrate to the dielectric film precursor. Next, method 400 comprises, at step 410, forming a gas mixture comprising a halogen-containing precursor, a reactant, and an inert gas. In some examples, the halogen-containing precursor can comprise one or more of HF, F₂, NF₃, SF₄, SF₆, ClF₃, ClF₅, BF₃, PF₃, a fluorocarbon, a chlorofluorocarbon, a chalcogen, a hydrofluorocarbon or an interhalogen as shown at step 412. In other examples, the halogen-containing precursor can comprise one or more of a chlorine-containing species, a bromine-containing species, or an iodine-containing species, as indicated at step 414. The inert gas can comprise He, Ne, Ar, Kr, Xe, N₂, or a combination of two or more thereof, as examples. Further, the reactant can comprise O₂, O₃, H₂O₂, H₂O vapor, N₂O, and/or other nitrogen oxides, as examples. The term “forming a gas mixture” generally represents either of or both of mixing gases before introducing the gas mixture into the processing chamber, or mixing gases in the processing chamber. In some examples, the halogen-containing precursor is introduced into the processing chamber before the reactant. As a more specific example, after purging the processing chamber, a fluorine-containing precursor can first be introduced into the processing chamber in the absence of the reactant. Then, the fluorine-containing precursor can be introduced together with the reactant and inert gas for a predetermined time period, while forming a plasma in the processing chamber, as explained below. Next, introduction of the fluorine-containing precursor can be ceased, while introduction of the reactant and inert gas into the plasma are continued. Then, the plasma can be extinguished, introduction of the reactant can be ceased, and the chamber can be purged.

In some examples, the gas mixture can comprise hydrogen, as indicated at step 416. In such examples, the hydrogen can inhibit etching and thereby facilitate incorporating fluorine into the dielectric film.

Continuing, method 400 further comprises, at step 418, forming a plasma comprising the gas mixture. The plasma forms reactive halogen-containing species from the halogen-containing precursor. For example, where the plasma comprises a fluorine-containing precursor such as HF, F₂, NF₃, SF₄, SF₆, BF₃, PF₃, or a fluorocarbon, the plasma converts at least some of the fluorine-containing precursor into excited fluorine species. The excited fluorine species are then incorporated into the growing film as Si—F bonds. The plasma also forms reactive oxidant species from the reactant. Where the reactant comprises an oxygen-containing reactant, the plasma can form reactive oxygen-containing species to form an oxide dielectric film. In some examples, the plasma can comprise an in-situ plasma. In other examples, the plasma can comprise a remote plasma. The plasma can comprise a capacitively-coupled radiofrequency plasma, an inductively coupled radiofrequency plasma, or a microwave plasma, as examples. In some examples, the radiofrequency power used to form the plasma can have a power level of between 50 and 6500 W. In more specific examples, the radiofrequency power can have a power level of between 1000 and 4500 W. In further examples, the radiofrequency power plasma can have a power level outside of these ranges. Likewise, the radiofrequency power have any suitable frequency. In some examples, the radiofrequency power has a frequency of 13.56 MHz. Other examples of suitable frequencies include 400 kHz, 27 MHz, 60 Mz, and 90 MHz. In some examples, two or more frequencies of radiofrequency power can be used to form a plasma. In some such examples, RF power of a first frequency can have a power in a range of 50 W to 6500 W, and RF power of a second frequency can have a power in a range of 100 W to 5000 W, where the second frequency is lower than the first frequency.

Method 400 further comprises reacting the dielectric film precursor adsorbed to the substrate with the reactive halogen species and the reactive species generated from the reactant. This forms the halogen-doped dielectric film, as indicated at step 420. In this manner, the dielectric film layer formed by the ALD cycle is doped with the halogen. As such, a doping step between the ALD cycle and a next ALD cycle can be omitted. Likewise, a post-deposition doping process, such as the example illustrated in FIG. 2, also can be omitted.

After forming the halogen-doped dielectric film layer at step 420, the processing chamber is again purged at step 422. Then, it is determined at step 424 whether all ALD cycles in the deposition process have been performed. If not, then method 400 returns to step 402, where the substrate is again exposed to the dielectric film precursor. On the other hand, if it is determined at step 424 that all ALD cycles have been completed, then method 400 ends.

Thus, the disclosed examples can be used to form halogen-doped dielectric films, including those in HAR features, more efficiently than methods that alternate ALD cycles with halogen doping steps. In some examples, FSG films having a dielectric constant of between 3.6 and 3.7 may be formed. In further examples, FSG films having a dielectric constant between 3.3 and 3.7 may be formed. The disclosed examples can increase substrate throughput compared to performing a halogen doping process after each ALD cycle. Also, the disclosed examples can utilize a halogen-containing precursor more efficiently than performing a halogen doping step after each ALD cycle.

A post-ALD halogen exposure process also can be used to treat a seam region in an ALD gapfill film. A gap is a recessed feature formed in a substrate surface. Gaps in substrate surfaces often are filled with other materials in an integrated circuit manufacturing process. As an example, a gap can be filled with a dielectric material, such as silicon oxide or a silicon oxide-based material (e.g. silicon oxynitride (SiON). ALD can be used to fill a gap with such a material in a layer by layer manner. Each film layer deposited in the gap causes the width of the open area of the gap to decrease. Eventually, a seam region forms where two or more growth fronts of the ALD-deposited film meet. The seam region can have different properties compared to the bulk region of the film in the gap, such as a different density. The different properties can potentially lead to integration issues, such as structural instability and/or shorting. Such issues can be mitigated in various manners. As one example, a deposition-etch-deposition (DED) process can be used in which dry etching and/or sputtering steps are used between some or all ALD deposition cycles. The dry etching and/or sputtering steps can lead to a v-shaped film growth, wherein the gap is filled in a bottom-up manner. Another example is the use of an inhibitor that inhibits film formation (e.g. by inhibiting adsorption of precursors and/or nucleation of a film). The inhibitor can be deposited onto the substrate in a manner that causes a first concentration of inhibitor to be adsorbed to the substrate in a gap closer to an opening of the gap, and a second concentration of inhibitor to be adsorbed to the substrate in the gap closer to the bottom of the gap. The second concentration is lower than the first concentration. This allows for bottom-up gapfill to occur.

However, both DED and inhibited ALD methods utilize additional process steps for the etching/sputtering and inhibitor deposition steps. The additional process steps can increase processing times and decrease throughout compared to processes that omit the etching/sputtering and inhibitor deposition steps.

It has been found that exposing a silicon oxide-based gapfill film to a fluorine-containing plasma can improve the properties of a seam in the gapfill film relative to a gapfill film that is not exposed to a fluorine-containing plasma. Unlike the above-described DED and inhibited ALD processes, the fluorine-containing plasma treatment can be performed in a post-ALD step. This can help increase throughput and lower processing complexity compared to DED and inhibited ALD methods.

As a more specific example, anhydrous hydrogen fluoride (HF) can be used as a fluorine-containing precursor to improve seam quality in a silicon oxide gapfill film. As mentioned above, hydrogen fluoride can etch SiO₂ in the presence of water. However, it has been found that a plasma treatment using anhydrous hydrogen fluoride improves seam quality of silicon oxide gapfill films. Silicon oxide gapfill films can comprise a relatively higher concentration of terminal-OH groups in seam regions than in other film regions. However, during a post-ALD HF plasma treatment, fluorine species in the plasma can remove-OH terminal groups from the seam regions. Removal of —OH groups can improve Si—O—Si cross-linking. This can improve seam quality by increasing density and increasing etch resistance.

In various examples, a post-ALD HF plasma treatment can be performed following TALD or PEALD. After depositing a silicon oxide gapfill film, a plasma is formed using a gas mixture comprising anhydrous HF and an inert gas. Any suitable inert gas can be used, such as Ar, He, Ne, and N₂. In some more specific examples, the gas mixture comprises HF, Ar, and N₂. In some such examples, the post-ALD HF plasma treatment comprises flowing HF into the processing chamber at a rate of 50-300 sccm, flowing Ar at a rate of 500 to 3000 sccm, and flowing N₂ at a rate of 400 to 2400 sccm. In other examples, flow rates outside these ranges can be used.

The post-ALD plasma treatment can be performed at any suitable conditions. Examples of suitable processing conditions include pressures of 1 to 20 Torr and temperatures of 250° C. to 750° C. The post-ALD plasma treatment can be performed for any suitable duration. In some examples, a duration within a range of 1 minute to 10 minutes can be used. In other examples, values outside these ranges can be used.

Any suitable plasma conditions can be used for the post-ALD plasma treatment. In various examples, the plasma can comprise a capacitively-coupled radiofrequency plasma, an inductively coupled radiofrequency plasma, or a microwave plasma, as examples. In some examples, the radiofrequency power used to form the plasma can have a power level of between 50 and 6500 W. In more specific examples, the radiofrequency power can have a power level of between 1000 and 4500 W. In some examples, a four-station processing tool can perform a post-ALD plasma treatment using radiofrequency power of approximately 5000 W. In further examples, the radiofrequency power plasma can have a power level outside of these ranges. Likewise, the radiofrequency power can have any suitable frequency. In some examples, the radiofrequency power has a frequency of 13.56 MHz. Other examples of suitable frequencies include 400 kHz, 27 MHz, 60 Mz, and 90 MHz. In some examples, two or more frequencies of radiofrequency power can be used to form a plasma, as described above.

Various experiments found that a post-ALD plasma treatment successfully lowered a wet etch rate (WER) of a film. In one experiment, an as-deposited TALD SiO₂ film exhibited a WER of ~2.5 Å/s. Upon treating the film with an anhydrous HF plasma, the WER decreased to ~1.0 Å/s. In another experiment, an as-deposited TALD SiO₂ film exhibited a WER of ~2.7 Å/s and decreased to a WER of ~0.25 Å/s following an anhydrous HF plasma treatment.

Various TALD films were analyzed using Fourier-transform infrared spectroscopy (FTIR) before and after an anhydrous HF plasma treatment. The FTIR analysis showed presence of Si—F bonding in the film following the plasma treatment. Further, the Si—O band was blueshifted. FTIR analysis of the TALD films also showed elimination of an —OH band at 3656 cm⁻¹ following the plasma treatment.

In some examples, a NH₃ plasma treatment optionally can be performed on the ALD gapfill film after performing the post-ALD HF plasma treatment. The NH₃ plasma treatment can increase film density, and may remove at least some F from the SiO₂ gapfill film.

Further, in other examples, a post-ALD annealing treatment can be used rather than a plasma treatment. For example, in some experiments, an annealing process at 950° C. using nitrogen with H₂/O₂ co-flow was found to improve seam quality for certain ALD films.

The example ALD methods described above can be implemented on a processing tool configured for temporal ALD, such as processing tool 100 of FIG. 1. Temporal ALD generally represents processes that use temporal control of gas flow and radiofrequency power to achieve the sequential reaction steps of an ALD process to form film layers on a substrate while the substrate is stationary on a pedestal at a processing station. In other examples, spatial ALD can be used to perform the above-described methods. Spatial ALD processes involve moving a substrate between different reaction zones, where each zone is configured for a specific process step. As an example, a processing chamber can be configured to flow a plurality of different reactant gases over a respective plurality of different reaction zones. Reaction zones can be separated by inert gas flow, for example. Then, a substrate support can rotate a substrate through the different reaction zones.

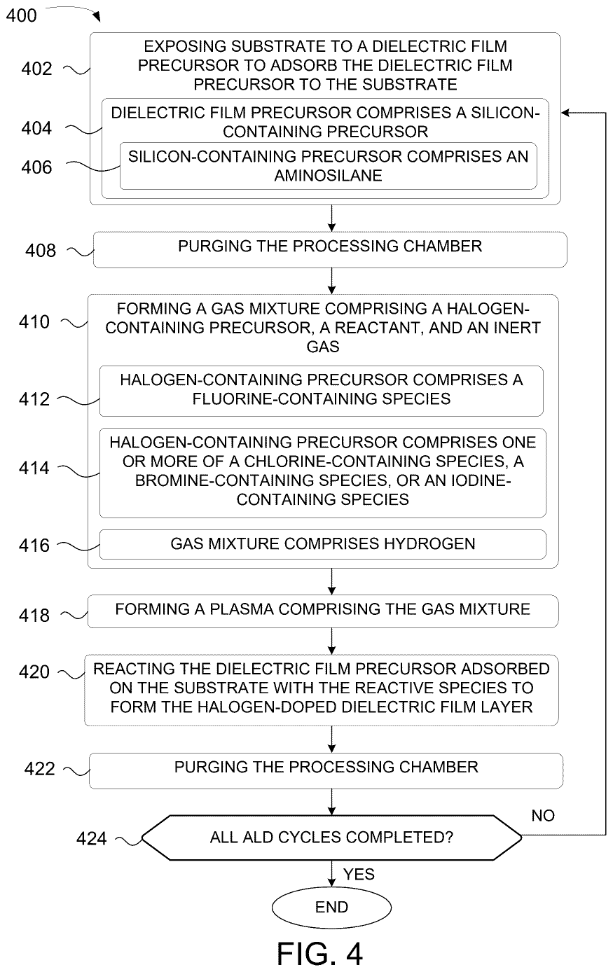

FIG. 5 schematically shows reaction zones in an example spatial ALD process 500. Spatial ALD process 500 comprises a first reaction zone 502 and a second reaction zone 504. Reaction zones are separated by purge zones 506, 508. First reaction zone 502 is configured as a dosing step of the ALD process. During ALD processing, first reaction zone 502 comprises continuous flow of a film precursor 510. Examples of film precursor 510 include silicon-containing precursors and halogen-containing precursors, such as those listed above.

Additionally, second reaction zone is configured as a conversion step of the ALD process. During ALD processing, second reaction zone comprises continuous flow of a reactant compound 512. Examples of reactant compound 512 include oxidants to oxidize a silicon-containing precursor or other dielectric film precursor. Example oxidants include oxygen, ozone, one or more oxides of nitrogen (e.g. nitrous oxide), water vapor, and hydrogen peroxide. In some examples, a mixture of two or more different oxidants can be used. Further examples of reactant compound 512 include nitrogen (N₂), ammonia (NH₃), or other nitrogen-containing reactant to form a silicon nitride film. In further examples, reactant compound 512 can comprise a reactant that can be used to form silicon carbide from a silicon-containing precursor. Examples include carbon-containing molecules that are gas phase under processing conditions. More specific examples can include the carbon-containing precursors listed above.

Additionally, purge zones 506, 508 are configured for continuous flow of an inert gas 514. Examples of inert gases include He, Ne, Ar, Kr, and N₂. Flow of inert gas 514 helps to remove excess film precursor or reactant compound from a substrate surface.

During an ALD cycle, a substrate 520 is moved by substrate support 600 sequentially through first reaction zone 502, purge zone 506, second reaction zone 504, and purge zone 508. In this manner, the substrate is exposed to film precursor 510 at first reaction zone 502. Then, excess film precursor can be purged from substrate surfaces at purge zone 506. Next, the substrate 520 is exposed to reactant compound 512 at second reaction zone 504. Then, excess reactant compound 512 can be purged from substrate surfaces at purge zone 508. The substrate support 600 then can move substrate 520 to first reaction zone 502 to begin another ALD cycle.

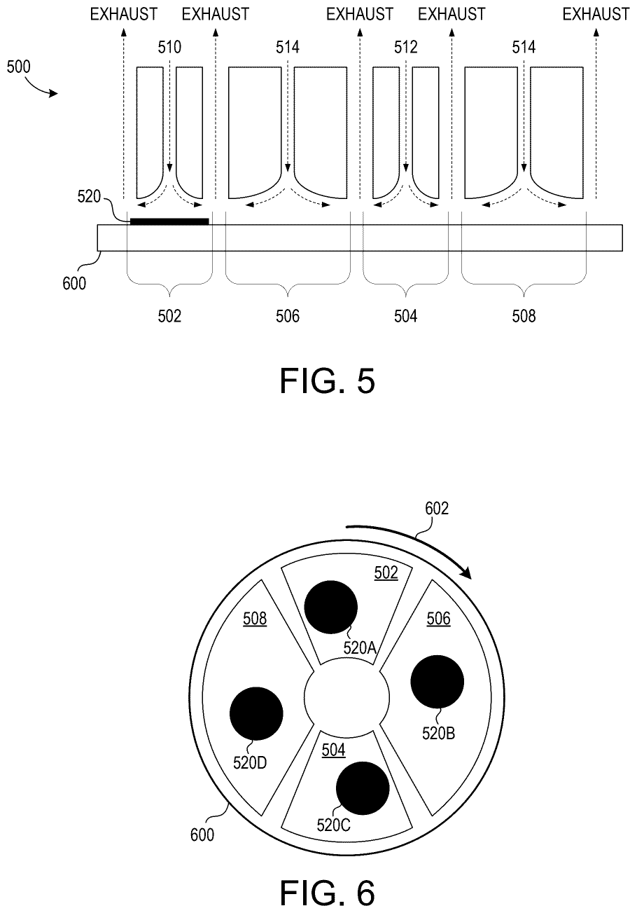

FIG. 6 schematically shows an overhead view of an example embodiment of substrate support 600. As shown in FIG. 6, substrate support 600 comprises a circular shape. Substrate support 600 supports four substrates 520A, 520B, 520C, 520D. During ALD processing substrate support 600 is configured to rotate substrates 520A, 520B, 520C, 520D clockwise through first reaction zone 502, purge zone 506, second reaction zone 504, and purge zone 508, as indicated by arrow 602. While the example depicted in FIG. 6 shows four substrates being processed, in other examples, any suitable number of substrates can be processed in parallel using spatial ALD process 500.

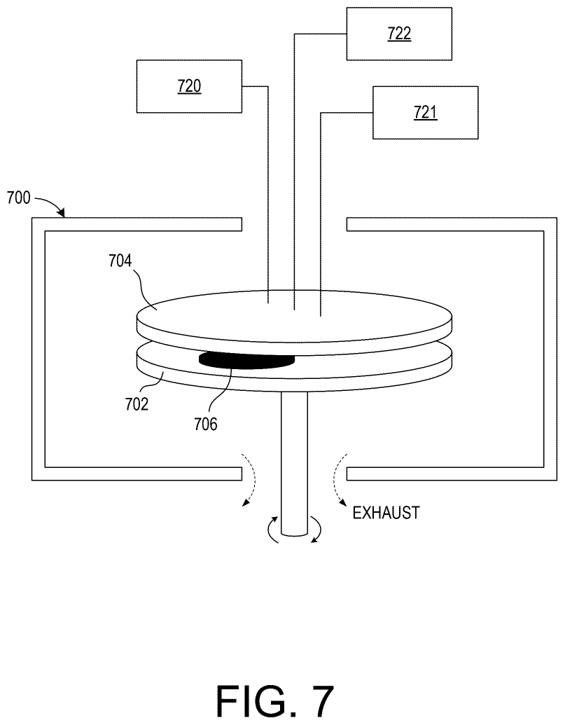

FIG. 7 schematically shows an example processing chamber 700 configured for spatial ALD. Processing chamber 700 comprises a substrate support 702 and a top plate 704. Substrate support 702 is configured to support one or more substrates 706. In some examples, substrate support 702 comprises a substrate heater configured to heat substrate 706. In other examples, a heater can be located elsewhere in processing chamber 700.

Top plate 704 comprises gas inlets configured to receive gas from one or more gas sources. In the depicted example, top plate 704 receives gas from a film precursor source 720, a reactant compound source 721, and an inert gas source 722.

Top plate 704 further comprises one or more regions each comprising a respective plurality of outlet holes. The outlet holes are disposed on a surface facing substrate support 702. Top plate 704 is configured to flow a selected processing gas through outlet holes of each region. In this manner, the processing chamber 700 can form different reaction zones (e.g., first reaction zone 502, second reaction zone 504) between substrate support 702 and top plate 704 corresponding to the different regions of top plate 704. Additionally, by flowing an inert gas from inert gas source 722 through outlet holes in a selected region, the processing chamber can form a purge zone between substrate support 702 and top plate 704.

Top plate 704 is stationary. Substrate support 702 is configured to rotate relative to top plate 704. During spatial ALD process, substrate 702 rotates, thereby moving substrate 706 sequentially through the reaction zones, as illustrated in FIG. 6 above. The time duration that substrate 706 is within each reaction zone can be adjusted by controlling the rotation rate of substrate support 702. As such, various aspects of spatial ALD processing can be controlled by controlling the rotation of substrate support 702. Further spatial ALD processing conditions include gas flow rates, pressure, and temperature.

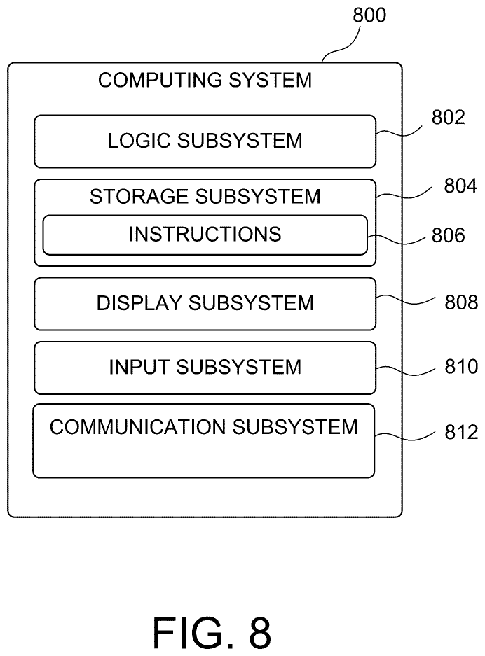

In some embodiments, the methods and processes described herein can be tied to a computing system of one or more computing devices. In particular, such methods and processes can be implemented as a computer-application program or service, an application-programming interface (API), a library, and/or other computer-program product. FIG. 8 schematically shows an example of a computing system 800 that can enact one or more of the methods and processes described above. Computing system 800 is shown in simplified form. Computing system 800 can take the form of one or more personal computers, server computers, tablet computers, network computing devices, and/or other computing devices. Controller 140 in FIG. 1 is an example of computing system 800.

Computing system 800 includes a logic subsystem 802 and a storage subsystem 804. Computing system 800 can optionally include a display subsystem 808, input subsystem 810, communication subsystem 812, and/or other components not shown in FIG. 8.

Logic subsystem 802 includes one or more physical devices configured to execute instructions 806. For example, the logic subsystem can be configured to execute instructions that are part of one or more applications, services, programs, routines, libraries, objects, components, data structures, or other logical constructs. Such instructions can be implemented to perform a task, implement a data type, transform the state of one or more components, achieve a technical effect, or otherwise arrive at a desired result. As examples, logic subsystem can execute instructions to implement method 200 and method 400 on a processing tool.

The logic subsystem can include one or more processors configured to execute software instructions. Additionally or alternatively, the logic subsystem can include one or more hardware or firmware logic devices configured to execute hardware or firmware instructions. Processors of the logic subsystem can be single-core or multi-core, and the instructions executed thereon can be configured for sequential, parallel, and/or distributed processing. Individual components of the logic subsystem optionally can be distributed among two or more separate devices, which can be remotely located and/or configured for coordinated processing. Aspects of the logic subsystem can be virtualized and executed by remotely accessible, networked computing devices configured in a cloud-computing configuration.

Storage subsystem 804 includes one or more physical devices configured to hold instructions 806 executable by the logic subsystem to implement the methods and processes described herein. For example, storage subsystem 804 can comprise instructions executable to perform method 200 and method 400. When such methods and processes are implemented, the state of storage subsystem 804 can be transformed—e.g., to hold different data.

Storage subsystem 804 can include removable and/or built-in devices. Storage subsystem 804 can include optical memory (e.g., CD, DVD, HD-DVD, Blu-Ray Disc, etc.), semiconductor memory (e.g., RAM, EPROM, EEPROM, etc.), and/or magnetic memory (e.g., hard-disk drive, floppy-disk drive, tape drive, MRAM, etc.), among others. Storage subsystem 804 can include volatile, nonvolatile, dynamic, static, read/write, read-only, random-access, sequential-access, location-addressable, file-addressable, and/or content-addressable devices.

It will be appreciated that storage subsystem 804 includes one or more physical devices. However, aspects of the instructions described herein alternatively can be propagated by a communication medium (e.g., an electromagnetic signal, an optical signal, etc.) that is not held by a physical device for a finite duration.

Aspects of logic subsystem 802 and storage subsystem 804 can be integrated together into one or more hardware-logic components. Such hardware-logic components can include field-programmable gate arrays (FPGAs), program- and application-specific integrated circuits (PASIC/ASICs), program- and application-specific standard products (PSSP/ASSPs), system-on-a-chip (SOC), and complex programmable logic devices (CPLDs), for example.

When included, display subsystem 808 can be used to present a visual representation of data held by storage subsystem 804. This visual representation can take the form of a graphical user interface (GUI). As the herein described methods and processes change the data held by the storage subsystem, and thus transform the state of the storage subsystem, the state of display subsystem 808 can likewise be transformed to visually represent changes in the underlying data. Display subsystem 808 can include one or more display devices utilizing virtually any type of technology. Such display devices can be combined with logic subsystem 802 and/or storage subsystem 804 in a shared enclosure, or such display devices can be peripheral display devices.

When included, input subsystem 810 can comprise or interface with one or more user-input devices such as a keyboard, mouse, or touch screen. In some embodiments, the input subsystem can comprise or interface with selected natural user input (NUI) componentry. Such componentry can be integrated or peripheral, and the transduction and/or processing of input actions can be handled on- or off-board . . .

When included, communication subsystem 812 can be configured to communicatively couple computing system 800 with one or more other computing devices. Communication subsystem 812 can include wired and/or wireless communication devices compatible with one or more different communication protocols. As examples, the communication subsystem can be configured for communication using a wireless telephone network, or a wired or wireless local- or wide-area network. In some embodiments, the communication subsystem can allow computing system 800 to send and/or receive messages to and/or from other devices using a network such as the Internet.

It will be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated and/or described may be performed in the sequence illustrated and/or described, in other sequences, in parallel, or omitted. Likewise, the order of the above-described processes may be changed.

The subject matter of the present disclosure includes all novel and non-obvious combinations and sub-combinations of the various processes, systems and configurations, and other features, functions, acts, and/or properties disclosed herein, as well as any and all equivalents thereof.

1. A method of forming a halogen-doped dielectric film, the method comprising:
forming, on a substrate, a dielectric film comprising a plurality of dielectric film layers; and
after forming the dielectric film, performing a plasma doping process comprising:
introducing a halogen-containing precursor into a plasma; and
exposing the dielectric film to reactive halogen-containing species generated in the plasma from the halogen-containing precursor, thereby forming the halogen-doped dielectric film.

2. The method of claim 1, wherein the halogen-containing precursor comprises one or more of fluorine, hydrogen fluoride, nitrogen trifluoride, sulfur tetrafluoride, sulfur hexafluoride, chlorine trifluoride, chlorine pentafluoride, boron trifluoride, phosphorus trifluoride, a fluorocarbon, a chlorofluorocarbon, a chalcogen, a hydrofluorocarbon, or an interhalogen.

3. The method of claim 1, wherein the halogen-containing precursor comprises anhydrous hydrogen fluoride.

4. The method of claim 1, wherein the halogen-containing precursor comprises one or more of a chlorine-containing species, a bromine-containing species, or an iodine-containing species.

5. The method of claim 1, wherein the dielectric film comprises silicon oxide.

6. The method of claim 1, wherein a dielectric constant of the halogen-doped dielectric film is lower than a dielectric constant of the dielectric film.

7. The method of claim 1, wherein forming the halogen-doped dielectric film comprises forming a halogen-doped dielectric film in which the halogen extends through a thickness of the halogen-doped dielectric film.

8. The method of claim 1, further comprising heating the substrate to a temperature in a range of 23-1200° C. while performing the plasma doping process.

9. A method of forming a halogen-doped dielectric film, the method comprising:
performing a plurality of an atomic layer deposition cycles, each atomic layer deposition cycle comprising:
exposing a substrate in a processing chamber to a dielectric film precursor to adsorb the dielectric film precursor to the substrate;
forming a gas mixture in the processing chamber, the gas mixture comprising a halogen-containing precursor, an oxidant, and an inert gas;
forming a plasma comprising the gas mixture to form reactive halogen-containing species and reactive oxidant species; and
reacting the dielectric film precursor adsorbed to the substrate with the reactive halogen-containing species and the reactive oxidant species to form the halogen-doped dielectric film.

10. The method of claim 9, wherein the gas mixture further comprises hydrogen.

11. The method of claim 9, wherein the dielectric film precursor comprises a silicon-containing precursor.

12. The method of claim 11, wherein the silicon-containing precursor comprises an aminosilane.

13. The method of claim 9, wherein the halogen-containing precursor comprises a fluorine containing precursor.

14. The method of claim 9, wherein the halogen-containing precursor comprises one or more of fluorine, hydrogen fluoride, nitrogen trifluoride, sulfur tetrafluoride, sulfur hexafluoride, chlorine trifluoride, chlorine pentafluoride, boron trifluoride, phosphorus trifluoride, a fluorocarbon, a chlorofluorocarbon, a chalcogen, a hydrofluorocarbon, or an interhalogen.

15. The method of claim 9, wherein the halogen-containing precursor comprises anhydrous hydrogen fluoride.

16. The method of claim 9, wherein the halogen-containing precursor comprises one or more of a chlorine-containing species, a bromine-containing species, or an iodine-containing species.

17. A processing tool, comprising:
a processing chamber;
a plasma generator;
one or more gas inlets into the processing chamber;
flow control hardware fluidly connecting one or more gas sources to the one or more gas inlets; and
a controller configured to
control the processing tool to perform an atomic layer deposition process comprising a plurality of atomic layer deposition cycles to form a dielectric film on a substrate in the processing chamber;
after performing the atomic layer deposition process comprising the plurality of atomic layer deposition cycles, control the plasma generator to form a plasma; and
control the flow control hardware to introduce a halogen-containing precursor into the plasma to generate reactive halogen-containing species to dope the dielectric film with a halogen.

18. The processing tool of claim 17, further comprising a substrate heater, and wherein the controller is configured to control the substrate heater to heat the substrate to a substrate temperature in a range of 23-1200° C. while exposing the dielectric film to the reactive halogen-containing species.

19. The processing tool of claim 17, further comprising a halogen-containing precursor supply.

20. The processing tool of claim 19, wherein the halogen-containing precursor supply comprises one or more of fluorine, hydrogen fluoride, nitrogen trifluoride, sulfur tetrafluoride, sulfur hexafluoride, chlorine trifluoride, chlorine pentafluoride, boron trifluoride, phosphorus trifluoride, a fluorocarbon, a chlorofluorocarbon, a chalcogen, a hydrofluorocarbon, or an interhalogen.
